(19) United States
(12) Patent Application Publication
(10) Pub. No.: US 2024/0120212 A1
(43) Pub. Date: Apr. 11, 2024

(54) SUBSTRATE TREATING METHOD, SUBSTRATE TREATING APPARATUS AND SUBSTRATE TREATING LIQUID

(71) Applicant: SCREEN Holdings Co., Ltd., Kyoto (JP)

(72) Inventors: Shogo KUNIEDA, Kyoto (JP); Yuta SASAKI, Kyoto (JP); Yosuke HANAWA, Kyoto (JP)

(21) Appl. No.: 18/452,977

(22) Filed: Aug. 21, 2023

(30) Foreign Application Priority Data
Sep. 26, 2022 (JP) 2022-152781

(51) Int. Cl. H01L 21/67; C11D 7/26; C11D 7/28; C11D 7/50; C11D 11/00; H01L 21/02

(52) U.S. Cl. CPC H01L 21/67028; C11D 7/261; C11D 7/28; C11D 7/5018; C11D 11/0023; H01L 21/02057; B08B 3/022

(57) ABSTRACT

A substrate treating method according to the present invention is a substrate treating method for treating a pattern-formed surface of a substrate W, the substrate treating method including: a supply process of supplying a substrate treating liquid containing a sublimable substance and a solvent to the pattern-formed surface; a solidification process of evaporating the solvent in a liquid film of the substrate treating liquid supplied to the pattern-formed surface in the supply process, depositing the sublimable substance, and forming a solidified film containing the sublimable substance; and a sublimation process of sublimating the solidified film and removing the solidified film, in which the sublimable substance contains at least one of 2,5-dimethyl-2,5-hexanediol and 3-trifluoromethylbenzoic acid.

### FIELD OF THE INVENTION

The present invention relates to a substrate treating method, a substrate treating apparatus, and a substrate treating liquid for removing liquid adhering to various substrates (hereinafter, referred to as a “substrate”) from the substrate such as a semiconductor substrate, a glass substrate for a photomask, a glass substrate for a liquid crystal display, a glass substrate for a plasma display, a substrate for a field emission display (FED), a substrate for an optical disk, a substrate for a magnetic disk, and a substrate for a magneto-optical disk.

### BACKGROUND OF THE INVENTION

In recent years, with miniaturization of a pattern formed on a substrate such as a semiconductor substrate, an aspect ratio (a ratio of a height to a width of a patterned protrusion) of a protrusion of a pattern having protrusions and recesses has been increased. For this reason, there is a problem of so-called pattern collapse in which surface tension acting on an interface between a liquid such as a cleaning liquid or a rinse liquid entering the recess of the pattern and a gas in contact with the liquid attracts and collapses adjacent protrusions of the pattern during drying treatment.

As a drying technique for the purpose of preventing such collapse of the pattern, for example, JP 2012-243869 A discloses a substrate drying method for removing liquid on a substrate having a protrusion and recess pattern formed on the surface and drying the substrate. By this substrate drying method, a solution of a sublimable substance is supplied to the substrate, the recess of the pattern is filled with the solution, the solvent in the solution is dried, the recess of the pattern is filled with the sublimable substance in a solid state, the substrate is heated to a temperature higher than the sublimation temperature of the sublimable substance, and the sublimable substance is removed from the substrate. Thus, in this patent document, it is described that stress for collapsing the protrusion portion of the pattern, which may be generated due to the surface tension of the liquid on the substrate, can be suppressed from acting on the protrusion portion of the pattern, and the pattern collapse can be prevented.

In addition, JP 2017-76817 A discloses a manufacturing method using a solution obtained by dissolving a deposited substance such as cyclohexane-1,2-dicarboxylic acid in a solvent such as an aliphatic hydrocarbon in sublimation drying of a surface of a semiconductor substrate on which a fine pattern is formed. By this manufacturing method, the pattern collapse can be suppressed during drying of the semiconductor substrate after liquid treatment.

In addition, JP 2021-9988 A and JP 2021-10002 A disclose sublimation drying techniques capable of suppressing collapse of a pattern more favorably as compared with the sublimation drying methods disclosed in JP 2012-243869 A and JP 2017-76817 A. According to these patent documents, by using a substrate treating liquid containing cyclohexanone oxime and isopropyl alcohol as a sublimable substance, collapse of a pattern in a partial or local region can be favorably suppressed as compared with a conventional substrate treating liquid.

However, even when the sublimation drying method as described above is used, there is a problem that collapse of a pattern cannot be sufficiently prevented when the mechanical strength of the pattern is noticeably small.

### SUMMARY OF THE INVENTION

The present invention has been made in view of the above problem, and an object is to provide a substrate treating method, a substrate treating apparatus, and a substrate treating liquid capable of performing sublimation drying by further preventing collapse of a pattern formed on the surface of a substrate.

In order to solve the above problems, a substrate treating method according to the present invention is characterized by including a supply process of supplying a substrate treating liquid containing a sublimable substance and a solvent to a pattern-formed surface; a solidification process of evaporating the solvent in a liquid film of the substrate treating liquid supplied to the pattern-formed surface in the supply process, depositing the sublimable substance, and forming a solidified film containing the sublimable substance; and a sublimation process of sublimating the solidified film and removing the solidified film, in which the sublimable substance contains at least one of 2,5-dimethyl-2,5-hexanediol and 3-trifluoromethylbenzoic acid.

By the substrate treating method having the above configuration, for example, when a liquid is present on the pattern-formed surface of the substrate, the liquid can be removed while the collapse of a pattern is prevented by the principle of sublimation drying. Specifically, after the substrate treating liquid is supplied to the pattern-formed surface in the supply process, the solvent in the liquid film of the substrate treating liquid is evaporated, the sublimable substance is deposited, and a solidified film is formed in the solidification process. Subsequently, the solidified film is removed by sublimating the solidified film. Here, with the above configuration, a substrate treating liquid containing a sublimable substance of at least one of 2,5-dimethyl-2,5-hexanediol and 3-trifluoromethylbenzoic acid is used. Thus, even in the case of a pattern having a noticeably small mechanical strength as compared with a substrate treating liquid using a conventional sublimable substance, the collapse of a pattern can be favorably suppressed and sublimation drying can be performed.

In the above configuration, it is preferable to further include a thinning process of thinning the liquid film of the substrate treating liquid supplied to the pattern-formed surface in the supply process by rotating the substrate at a first rotation speed about a rotation axis parallel to a direction perpendicular to the pattern-formed surface, in which the solidification process is a process of rotating the substrate about the rotation axis at a second rotation speed higher than the first rotation speed and evaporating the solvent in the liquid film.

In addition, in the above configuration, it is preferable to use a solvent having a higher vapor pressure at room temperature than the sublimable substance as the solvent. This makes it easy to deposit a sublimable substance such as 2,5-dimethyl-2,5-hexanediol or the like by evaporation of the solvent, and a solidified film containing the sublimable substance can be favorably formed.

Further, in the above configuration, it is preferable that the solvent be at least one of methanol, butanol, isopropyl alcohol, and acetone.

In addition, in order to solve the above problems, a substrate treating apparatus according to the present invention is a substrate treating apparatus for treating a pattern-formed surface of a substrate, the substrate treating apparatus being characterized by including: a substrate holding portion that rotatably holds the substrate about a rotation axis parallel to a direction perpendicular to the pattern-formed surface; a supply portion that supplies a substrate treating liquid containing a sublimable substance and a solvent to the pattern-formed surface of the substrate held by the substrate holding portion; and a sublimation portion that sublimates a solidified film containing the sublimable substance and remove the solidified film, in which the substrate holding portion evaporates the solvent in a liquid film of the substrate treating liquid supplied to the pattern-formed surface by the supply portion, deposits the sublimable substance, and forms the solidified film containing the sublimable substance, and the sublimable substance in the substrate treating liquid supplied by the supply portion contains at least one of 2,5-dimethyl-2,5-hexanediol and 3-trifluoromethylbenzoic acid.

With the substrate treating apparatus having the above configuration, for example, when a liquid is present on the pattern-formed surface of the substrate, the liquid can be removed while the collapse of a pattern is prevented by the principle of sublimation drying. Specifically, the substrate holding portion holds the substrate so as to be rotatable about a rotation axis parallel to a direction perpendicular to the pattern-formed surface. In addition, the supply portion supplies the substrate treating liquid to the pattern-formed surface of the substrate held by the substrate holding portion. Here, the substrate holding portion evaporates the solvent from the liquid film of the substrate treating liquid by rotating the substrate. Thus, the sublimable substance can be deposited and a solidified film can be formed. Subsequently, the sublimation portion sublimates the solidified film containing the sublimable substance, and the solidified film can be removed. Here, with the above configuration, a substrate treating liquid containing a sublimable substance of at least one of 2,5-dimethyl-2,5-hexanediol and 3-trifluoromethylbenzoic acid is used. Thus, even in the case of a pattern having a noticeably small mechanical strength as compared with a substrate treating liquid using a conventional sublimable substance, the collapse of a pattern can be favorably suppressed and sublimation drying can be performed.

With the above configuration, the substrate holding portion preferably thins the liquid film of the substrate treating liquid supplied to the pattern-formed surface by the supply portion by rotating the substrate about the rotation axis, and rotates the substrate about the rotation axis at a second rotation speed higher than a first rotation speed when the liquid film of the substrate treating liquid is thinned and evaporates the solvent in the liquid film.

In addition, in the above configuration, it is preferable to use a solvent having a higher vapor pressure at room temperature than the sublimable substance as the solvent. This makes it easy to deposit a sublimable substance such as 2,5-dimethyl-2,5-hexanediol or the like by evaporation of the solvent, and a solidified film containing the sublimable substance can be favorably formed.

Further, in the above configuration, it is preferable that the solvent be at least one of methanol, butanol, isopropyl alcohol, and acetone.

In addition, in order to solve the above problems, a substrate treating liquid according to the present invention is a substrate treating liquid used for removing a liquid on a substrate having a pattern-formed surface, the substrate treating liquid being characterized by including: a sublimable substance; and a solvent, in which the sublimable substance contains at least one of 2,5-dimethyl-2,5-hexanediol and 3-trifluoromethylbenzoic acid.

With the above configuration, by containing at least one of 2,5-dimethyl-2,5-hexanediol and 3-trifluoromethylbenzoic acid as a sublimable substance in the substrate treating liquid, even in the case of a pattern having a noticeably small mechanical strength as compared with a substrate treating liquid using a conventional sublimable substance, the collapse of a pattern can be favorably suppressed and sublimation drying can be performed.

In addition, in the above configuration, the solvent preferably has a higher vapor pressure at room temperature than the sublimable substance. This makes it easy to deposit a sublimable substance such as 2,5-dimethyl-2,5-hexanediol or the like by evaporation of the solvent, and a solidified film containing the sublimable substance can be favorably formed.

Further, in the above configuration, it is preferable that the solvent be at least one of methanol, butanol, isopropyl alcohol, and acetone.

According to the present invention, it is possible to provide a substrate treating method, a substrate treating apparatus, and a substrate treating liquid capable of suppressing collapse of a pattern on a pattern-formed surface of a substrate and capable of favorably suppressing collapse of a pattern even with a pattern having a noticeably low mechanical strength as compared with a substrate treating liquid containing a conventional sublimable substance.

### BRIEF DESCRIPTION OF THE FIGURES

FIG. 1 is a plan view showing a schematic configuration of a substrate treating apparatus according to an embodiment of the present invention;

FIG. 2 is an explanatory view schematically showing a treating unit in the substrate treating apparatus;

FIG. 3A is a block diagram showing a schematic configuration of a substrate treating liquid storage portion;

FIG. 3B is an explanatory view showing a specific configuration of the substrate treating liquid storage portion;

FIG. 4 is a block diagram showing a schematic configuration of a gas storage portion in the substrate treating apparatus;

FIG. 5 is a flowchart for describing a substrate treating method using the substrate treating apparatus according to the present embodiment;

FIG. 6A is a schematic view showing a state of a substrate W after the end of a substrate treating liquid supply process;

FIG. 6B is a schematic view showing a state of the substrate W after the end of a thinning process;

FIG. 7A is a schematic view showing a state of the substrate W at the start of a solidification process;

FIG. 7B is a schematic view showing a state in which a solidified film is formed on a front surface of the substrate;

FIG. 7C is a schematic view showing a state in which the solidified film is removed by sublimation;

FIG. 8 is a graph showing an example of an image in which a thickness of a liquid film (thin film) of the substrate treating liquid on the substrate W decreases due to evaporation of a solvent; and

FIG. 9 is a graph showing a concentration calibration curve between a concentration of cyclohexanone oxime in the substrate treating liquid and a film thickness of a solidified film formed of cyclohexanone oxime.

### DETAILED DESCRIPTION OF THE INVENTION

An embodiment of the present disclosure will be described below.

In the present specification, the “substrate” refers to various substrates such as a semiconductor substrate, a glass substrate for a photomask, a glass substrate for a liquid crystal display, a glass substrate for a plasma display, a substrate for a field emission display (FED), a substrate for an optical disk, a substrate for a magnetic disk, and a substrate for a magneto-optical disk. In addition, in the present specification, the “pattern-formed surface” means a surface on which a protrusion and recess pattern is formed in an any region of the substrate regardless of whether the surface is planar, curved, or uneven. In addition, in the present specification, a substrate in which a circuit pattern or the like (hereinafter referred to as a “pattern”) is formed only on one main surface is taken as an example. Here, the pattern-formed surface (main surface) on which the pattern is formed is referred to as a “front surface”, and the main surface on the opposite side on which the pattern is not formed is referred to as a “back surface”. In addition, a surface of the substrate facing downward is referred to as a “lower surface”, and a surface of the substrate facing upward is referred to as an “upper surface”. Note that, in the present embodiment, the upper surface will be described as the front surface.

### (Substrate Treating Liquid)

First, a substrate treating liquid according to the present embodiment will be described.

The substrate treating liquid of the present embodiment contains a sublimable substance and a solvent. The substrate treating liquid of the present embodiment may be formed only of a sublimable substance and a solvent. The substrate treating liquid of the present embodiment functions to assist the drying treatment in the drying treatment for removing a liquid present on the pattern-formed surface of the substrate. Note that, in the present specification, the term “sublimability” means that a simple substance, a compound, or a mixture has a property of phase transition from a solid to a gas or from a gas to a solid without passing through a liquid, and the term “sublimable substance” means a substance having such sublimability.

The sublimable substance contains at least one (hereinafter may be referred to as “2,5-dimethyl-2,5-hexanediol or the like”) of 2,5-dimethyl-2,5-hexanediol (vapor pressure 0.18 Pa (20° C.)) and 3-trifluoromethylbenzoic acid. The sublimable substance may be formed only of 2,5-dimethyl-2,5-hexanediol or 3-trifluoromethylbenzoic acid.

2,5-dimethyl-2,5-hexanediol is represented by Chemical Formula (1) described below. In addition, 3-trifluoromethylbenzoic acid is represented by Chemical Formula (2) described below. These compounds can function as a sublimable substance in the substrate treating liquid of the present embodiment.

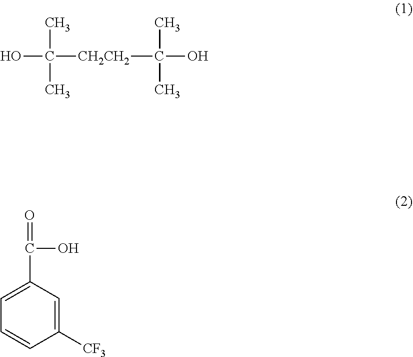

2,5-dimethyl-2,5-hexanediol or the like is preferably present in a state of being dissolved in the solvent in the substrate treating liquid. Here, in the present specification, the “state of being dissolved” means, for example, that 0.1 g or more of 2,5-dimethyl-2,5-hexanediol or the like is dissolved in 100 g of the solvent at 23° C.

The content (concentration) of 2,5-dimethyl-2,5-hexanediol or the like can be appropriately set according to, for example, the thickness of a solidified film of the substrate treating liquid formed on the pattern-formed surface of the substrate. For example, when 2,5-dimethyl-2,5-hexanediol is used as the sublimable substance, the content is preferably 2 vol % or more and 10 vol % or less, more preferably 2.3 vol % or more and 9.2 vol % or less, and particularly preferably 3 vol % or more and 6 vol % or less with respect to the total volume of the substrate treating liquid. By setting the content of 2,5-dimethyl-2,5-hexanediol to 2 vol % or more, collapse of a pattern can be more favorably suppressed even for a substrate having a fine pattern having a large aspect ratio. On the other hand, by setting the content of 2,5-dimethyl-2,5-hexanediol to 10 vol % or less, it is possible to suppress the film thickness of the solidified film from becoming excessively large and to prevent the collapse rate of the pattern from becoming excessively large. In addition, when 3-trifluoromethylbenzoic acid is used as the sublimable substance, the content is preferably 2 vol % or more and 6 vol % or less, more preferably 2.2 vol % or more and 5 vol % or less, and particularly preferably 2.2 vol % or more and 3 vol % or less with respect to the total volume of the substrate treating liquid. By setting the content of 3-trifluoromethylbenzoic acid to 2 vol % or more, collapse of a pattern can be more favorably suppressed even for a substrate having a fine pattern having a large aspect ratio. On the other hand, by setting the content of 3-trifluoromethylbenzoic acid to 6 vol % or less, it is possible to suppress the film thickness of the solidified film from becoming excessively large and to prevent the collapse rate of the pattern from becoming excessively large.

Note that, in the present embodiment, a known sublimable substance other than 2,5-dimethyl-2,5-hexanediol or the like may be contained in the substrate treating liquid as long as the effect of the present disclosure is not impaired. In this case, the content of another sublimable substance can be appropriately set according to the type and the like.

The solvent can function as a solvent in which 2,5-dimethyl-2,5-hexanediol or the like is dissolved. As the solvent, a solvent having a vapor pressure at room temperature higher than a vapor pressure at room temperature of a sublimable substance such as 2,5-dimethyl-2,5-hexanediol or the like is preferable. This facilitates evaporation of the solvent and deposition of a sublimable substance such as 2,5-dimethyl-2,5-hexanediol or the like. Note that, in the present specification, “room temperature” means that the temperature is in a temperature range of 5° C. or more and 35° C. or less, 10° C. or more and 30° C. or less, or 20° C. or more and 25° C. or less.

The solvent is preferably at least one of alcohols such as methanol (vapor pressure 12.8 kPa (20° C.)), butanol (0.6 kPa (20° C.)) and isopropyl alcohol (vapor pressure 4.4 kPa (20° C.)), and acetone (vapor pressure 24 kPa (20° C.)). Among these solvents, isopropyl alcohol is preferable in the present embodiment. This is because the vapor pressure of isopropyl alcohol at room temperature is higher than the vapor pressure of 2,5-dimethyl-2,5-hexanediol or the like at room temperature.

The method for producing the substrate treating liquid according to the present embodiment is not particularly limited, and examples include a method in which a crystalline material of 2,5-dimethyl-2,5-hexanediol or the like is added to the solvent so as to have a certain content at room temperature and atmospheric pressure. Note that “at atmospheric pressure” means an environment of 0.7 atm or more and 1.3 atm or less around standard atmospheric pressure (1 atm, 1013 hPa).

In the method for producing the substrate treating liquid, filtration may be performed after adding the crystalline material of 2,5-dimethyl-2,5-hexanediol or the like to the solvent. Thus, when the substrate treating liquid is supplied onto the pattern-formed surface of the substrate and used for removing the liquid, the generation of residues derived from the substrate treating liquid on the pattern-formed surface can be reduced or prevented. The filtration method is not particularly limited, and for example, filter filtration or the like can be adopted.

The substrate treating liquid of the present embodiment can be stored at room temperature. However, from the viewpoint of suppressing a change in the concentration of 2,5-dimethyl-2,5-hexanediol or the like due to evaporation of the solvent, it is preferable to store at a low temperature (for example, about 20° C.). In addition, in order to prevent evaporation of the solvent, it is more preferable to store the substrate treating liquid in a sealed dark place. When the substrate treating liquid stored at a low temperature is used, it is preferable to use the substrate treating liquid after setting the liquid temperature of the substrate treating liquid to a use temperature, ambient temperature, or the like from the viewpoint of preventing moisture from being mixed due to condensation.

### (Substrate Treating Apparatus)

### <Overall Configuration of Substrate Treating Apparatus>

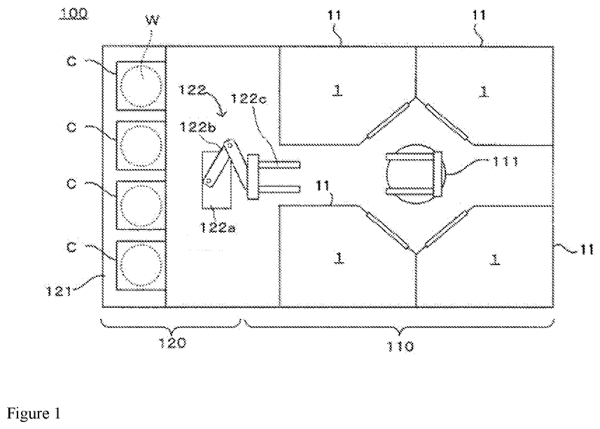

The substrate treating apparatus according to the present embodiment will be described with reference to FIG. 1. FIG. 1 is a plan view showing a schematic configuration of a substrate treating apparatus 100 according to the present embodiment.

The substrate treating apparatus 100 of the present embodiment is a single-wafer type substrate treating apparatus used for cleaning treatment (including rinse treatment) for removing contaminants such as particles adhering to a substrate and drying treatment after the cleaning treatment.

As shown in FIG. 1, the substrate treating apparatus 100 includes a substrate treating portion 110 that performs various types of treatment on the substrate W, and an indexer portion 120.

The indexer portion 120 has a function of supplying the substrate W to the substrate treating portion 110 or recovering the substrate W from the substrate treating portion 110. Specifically, the indexer portion 120 includes four container holding portions 121, and each of the container holding portions 121 is provided with one container C. Examples of the container C include a front opening unified pod (FOUP), a standard mechanical interface (SMIF) pod, and an open cassette (OC) that house a plurality of substrates W in a sealed state. Note that, in the present embodiment, a case where there are four container holding portions 121 will be described as an example, but the present disclosure is not limited thereto. It is sufficient if the number of the container holding portions 121 is plural.

In addition, the indexer portion 120 further includes a first conveyance portion 122 for conveying the substrate W. The first conveyance portion 122 is provided between the container holding portions 121 and the substrate treating portion 110. The first conveyance portion 122 includes a base portion 122a fixed to the device housing, an articulated arm 122b provided to be rotatable about a vertical axis with respect to the base portion 122a, and a hand 122c attached to a front end of the articulated arm 122b. The hand 122c has a structure in which the substrate W can be placed and held on the upper surface of the hand 122c. The first conveyance portion 122 can access the container C held by the container holding portion 121 and take out the untreated substrate W from the container C or store the treated substrate W in the container C.

The substrate treating portion 110 performs the cleaning treatment (including rinse treatment) or the drying treatment after the cleaning treatment on the substrate. The substrate treating portion 110 includes a second conveyance portion 111 disposed substantially at the center in plan view and four treating units 1 disposed to surround the second conveyance portion 111. As the second conveyance portion 111, for example, a substrate conveyance robot can be used. The second conveyance portion 111 randomly accesses each treating unit 1 and delivers the substrate W. The substrate treating portion 110 includes a plurality of treating units 1 to enable parallel processing of the plurality of substrates W.

### <Configuration of Treating Unit>

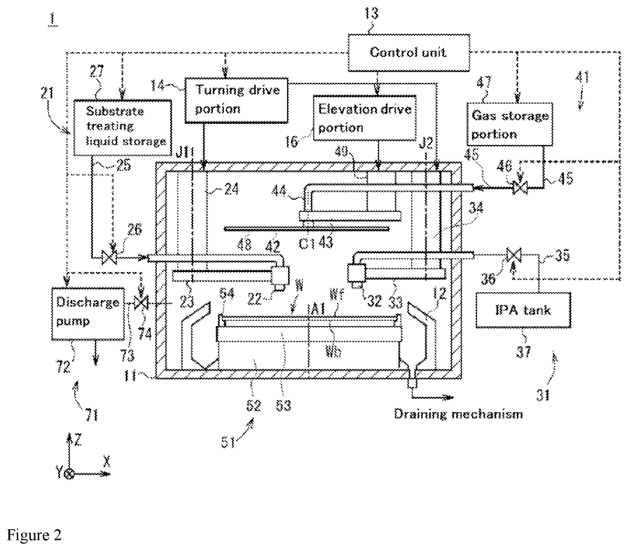

Next, a configuration of the treating unit 1 will be described with reference to FIGS. 2 to 4.

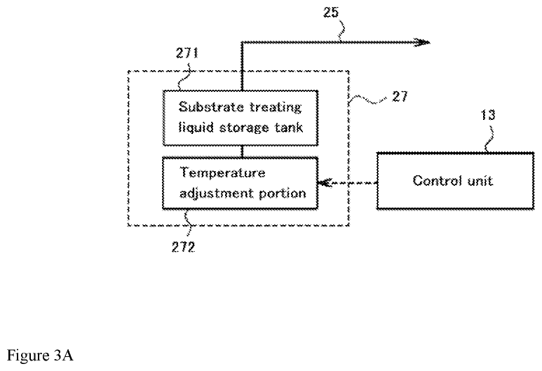

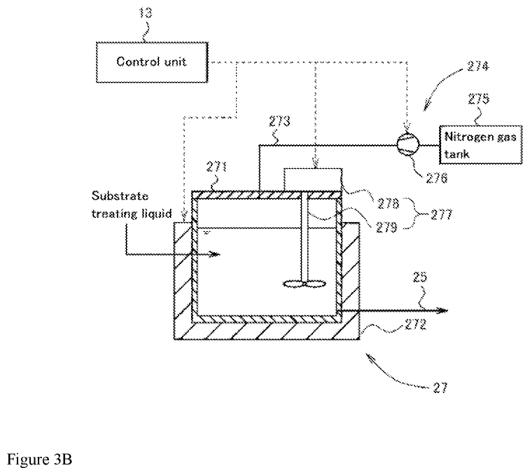

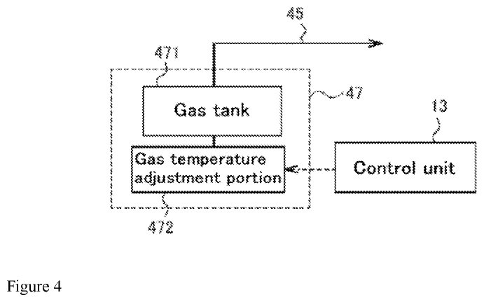

FIG. 2 is an explanatory view schematically showing the substrate treating apparatus according to the present embodiment. FIG. 3A is a block diagram showing a schematic configuration of a substrate treating liquid storage portion, and FIG. 3B is an explanatory view showing a specific configuration of the substrate treating liquid storage portion. FIG. 4 is a block diagram showing a schematic configuration of a gas storage portion. Note that in FIG. 2, XYZ orthogonal coordinate axes are appropriately indicated in order to clarify the directional relationship of the shown object. In the drawing, the XY plane represents a horizontal plane, and the +Z direction represents a vertically upward direction.

The treating unit 1 includes at least a chamber 11, which is a container for housing the substrate W, a substrate holding portion 51 for holding the substrate W, a treating liquid supply portion (supply portion) 21 for supplying a substrate treating liquid to the substrate W held by the substrate holding portion 51, an isopropyl alcohol (IPA) supply portion 31 for supplying IPA to the substrate W held by the substrate holding portion 51, a gas supply portion 41 (sublimation portion) for supplying a gas to the substrate W held by the substrate holding portion 51, a dispersion prevention cup 12 for collecting the IPA, the substrate treating liquid, and the like supplied to the substrate W held by the substrate holding portion 51 and discharged to the outside of the peripheral edge portion of the substrate W, and a turning drive portion 14 for independently turning and driving arms, which will be described below, of each portion of the treating unit 1.

The substrate holding portion 51 includes a rotation drive portion 52, a spin base 53, and chuck pins 54. The spin base 53 has a plane size slightly larger than the substrate W. In the vicinity of the peripheral edge portion of the spin base 53, a plurality of chuck pins 54 for gripping the peripheral edge portion of the substrate W is erected. The number of chuck pins 54 to be installed is not particularly limited, but it is preferable to provide at least three chuck pins in order to reliably hold the substrate W having a circular shape. In the present embodiment, three chuck pins are disposed at equal intervals along the peripheral edge portion of the spin base 53. Each of the chuck pins 54 includes a substrate support pin that supports the peripheral edge portion of the substrate W from below, and a substrate holding pin that presses an outer peripheral end surface of the substrate W supported by the substrate support pin and holds the substrate W.

Note that, in the present embodiment, a case where the substrate W is held by the spin base 53 and the chuck pins 54 will be described as an example, but the present disclosure is not limited to this substrate holding method. For example, a back surface Wb of the substrate W may be held by a suction method using such as a spin chuck.

The spin base 53 is coupled to the rotation drive portion 52. The rotation drive portion 52 rotates about an axis A1 along the Z direction in accordance with an operation command from a control unit 13. The rotation drive portion 52 includes a known belt, motor, and rotation shaft. When the rotation drive portion 52 rotates around the axis A1, the substrate W held by the chuck pins 54 above the spin base 53 rotates about a rotation axis parallel to a direction perpendicular to a front surface Wf of the substrate W, that is, about the axis A1 together with the spin base 53.

Next, the treating liquid supply portion (supply unit) 21 will be described.

The treating liquid supply portion 21 is a unit that supplies a substrate treating liquid to the pattern-formed surface of the substrate W. As shown in FIG. 2, the treating liquid supply portion 21 includes at least a nozzle 22, an arm 23, a turning shaft 24, a pipe 25, a valve 26, and a substrate treating liquid storage portion 27.

The nozzle 22 is attached to a front end portion of the arm 23 that is horizontally extended, and is disposed above the spin base 53. A rear end portion of the arm 23 is rotatably supported about an axis J1 by the turning shaft 24 that is extended in the Z direction, and the turning shaft 24 is fixed in the chamber 11. The arm 23 is coupled to the turning drive portion 14 via the turning shaft 24. The turning drive portion 14 is electrically connected to the control unit 13, and rotates the arm 23 about the axis J1 in accordance with an operation command from the control unit 13. The nozzle 22 also moves as a result of the rotation of the arm 23. Note that the nozzle 22 is normally disposed at a retracted position outside the peripheral edge portion of the substrate W and outside the dispersion prevention cup 12. When the arm 23 is rotated in accordance with an operation command of the control unit 13, the nozzle 22 is disposed at a position above a central portion (axis A1 or the vicinity of the axis A1) of the front surface Wf of the substrate W.

The valve 26 is electrically connected to the control unit 13 and is normally closed. Opening and closing of the valve 26 is controlled in accordance with an operation command of the control unit 13. When the valve 26 is opened in accordance with an operation command of the control unit 13, the substrate treating liquid is supplied from the nozzle 22 to the front surface Wf of the substrate W through the pipe 25.

As shown in FIGS. 3A and 3B, the substrate treating liquid storage portion 27 includes at least a substrate treating liquid storage tank 271, a stirring portion 277 that stirs the substrate treating liquid in the substrate treating liquid storage tank 271, a pressurizing portion 274 that pressurizes the substrate treating liquid storage tank 271 and sends out the substrate treating liquid, and a temperature adjustment portion 272 that heats the substrate treating liquid in the substrate treating liquid storage tank 271.

As shown in FIG. 3B, the stirring portion 277 includes a rotation portion 279 that stirs the substrate treating liquid in the substrate treating liquid storage tank 271, and a stirring control portion 278 that controls the rotation of the rotation portion 279. The stirring control portion 278 is electrically connected to the control unit 13. The rotation portion 279 includes a propeller-shaped stirring blade at a front end of a rotation shaft (a lower end of the rotation portion 279 in FIG. 3B), and when the control unit 13 gives an operation command to the stirring control portion 278 and the rotation portion 279 rotates, the stirring blade stirs the substrate treating liquid and the concentration of the sublimable substance in the substrate treating liquid and the temperature of the substrate treating liquid are made uniform.

In addition, the method of making the concentration and temperature of the substrate treating liquid in the substrate treating liquid storage tank 271 uniform is not limited to the above-described method, and a known method such as a method of separately providing a pump for circulation and circulating the substrate treating liquid can be used.

The pressurizing portion 274 includes a nitrogen gas tank 275, which is a supply source of an inert gas for pressurizing the inside of the substrate treating liquid storage tank 271, a pump 276 for pressurizing the nitrogen gas, and a pipe 273. The nitrogen gas tank 275 is line-connected to the substrate treating liquid storage tank 271 through the pipe 273, and the pump 276 is interposed in the pipe 273.

The temperature adjustment portion 272 is electrically connected to the control unit 13, and performs temperature adjustment by heating or the like the substrate treating liquid stored in the substrate treating liquid storage tank 271 in accordance with an operation command of the control unit 13. The temperature adjustment is performed, for example, so that the sublimable substance dissolved in the substrate treating liquid is not deposited. Note that the upper limit of the temperature adjustment is preferably a temperature lower than the boiling point of the solvent such as IPA. This makes it possible to prevent evaporation of the solvent and prevent the substrate treating liquid having a desired composition from being unable to be supplied to the substrate W. In addition, the temperature adjustment portion 272 is not particularly limited, and for example, a known temperature adjustment mechanism such as a resistance heating heater, a Peltier element, or a pipe through which temperature-adjusted water passes can be used.

As shown in FIG. 2, the IPA supply portion 31 is a unit that supplies the IPA to the substrate W held by the substrate holding portion 51. The IPA supply portion 31 includes a nozzle 32, an arm 33, a turning shaft 34, a pipe 35, a valve 36, and an IPA tank 37.

The nozzle 32 is attached to a front end portion of the arm 33 that is horizontally extended, and is disposed above the spin base 53. A rear end portion of the arm 33 is rotatably supported about an axis J2 by the turning shaft 34 that is extended in the Z direction, and the turning shaft 34 is fixed in the chamber 11. The arm 33 is coupled to the turning drive portion 14 via the turning shaft 34. The turning drive portion 14 is electrically connected to the control unit 13, and rotates the arm 33 about the axis J2 in accordance with an operation command from the control unit 13. The nozzle 32 also moves as a result of the rotation of the arm 33. Note that the nozzle 32 is normally disposed at a retracted position outside the peripheral edge portion of the substrate W and outside the dispersion prevention cup 12. When the arm 33 is rotated in accordance with an operation command of the control unit 13, the nozzle 32 is disposed at a position above a central portion (axis A1 or the vicinity of the axis A1) of the front surface Wf of the substrate W.

The valve 36 is electrically connected to the control unit 13 and is normally closed. Opening and closing of the valve 36 is controlled in accordance with an operation command of the control unit 13. When the valve 36 is opened in accordance with an operation command of the control unit 13, the IPA is supplied from the nozzle 32 to the front surface Wf of the substrate W through the pipe 35.

The IPA tank 37 is line-connected to the nozzle 32 through the pipe 35, and the valve 36 is inserted in an intermediate part of the path of the pipe 35. The IPA is stored in the IPA tank 37, and the IPA in the IPA tank 37 is pressurized by a pump, which is not shown, and the IPA is sent from the pipe 35 in the direction of the nozzle 32.

Note that, in the present embodiment, the IPA is used in the IPA supply portion 31, but the present disclosure is not limited to the IPA as long as it is a liquid having solubility in a sublimable substance and deionized water (DIW). Examples of an alternative to the IPA in the present embodiment include methanol, ethanol, acetone, benzene, carbon tetrachloride, chloroform, hexane, decalin, tetralin, acetic acid, cyclohexanol, ether, and hydrofluoroether.

As shown in FIG. 2, the gas supply portion 41 is a unit that supplies gas to the substrate W held by the substrate holding portion 51, and includes a nozzle 42, an arm 43, a support shaft 44, a pipe 45, a valve 46, a gas storage portion 47, a shielding plate 48, an elevating mechanism 49, and a shielding plate rotation mechanism (not shown).

As shown in FIG. 4, the gas storage portion 47 includes a gas tank 471 that stores gas, and a gas temperature adjustment portion 472 that adjusts the temperature of the gas stored in the gas tank 471. The gas temperature adjustment portion 472 is electrically connected to the control unit 13, and performs temperature adjustment by heating or cooling the gas stored in the gas tank 471 in accordance with an operation command of the control unit 13. The gas temperature adjustment portion 472 is not particularly limited, and for example, a known temperature adjustment mechanism such as a Peltier element or a pipe through which temperature-adjusted water passes can be used.

In addition, as shown in FIG. 2, the gas storage portion 47 (in more detail, the gas tank 471) is line-connected to the nozzle 42 through the pipe 45, and the valve 46 is inserted in an intermediate part of the path of the pipe 45. The gas in the gas storage portion 47 is pressurized by a pressurizing unit, which is not shown, and sent to the pipe 45. Note that, since the pressurizing unit can be achieved by compressing and storing the gas in the gas storage portion 47 in addition to pressurization with a pump or the like, any pressurizing unit may be used.

The valve 46 is electrically connected to the control unit 13 and is normally closed. Opening and closing of the valve 46 is controlled in accordance with an operation command of the control unit 13. When the valve 46 is opened in accordance with an operation command of the control unit 13, an inert gas such as nitrogen gas stored in the gas tank 471 passes through the pipe 45 and is discharged through the nozzle 42.

The nozzle 42 is provided at a front end of the support shaft 44. In addition, the support shaft 44 is held at a front end portion of the arm 43 that is horizontally extended. Thus, the nozzle 42 is disposed above the spin base 53, in more detail, at a position above a central portion (axis A1 or the vicinity of the axis A1) of the front surface Wf of the substrate W.

The arm 43 extends in a substantially horizontal direction, and a rear end portion of the arm 43 is supported by the elevating mechanism 49. In addition, the arm 43 is connected to an elevation drive portion 16 via the elevating mechanism 49. Then, the elevation drive portion 16 is electrically connected to the control unit 13, and the elevating mechanism 49 is elevated in an up-down direction in accordance with an operation command from the control unit 13, and the arm 43 is also elevated integrally. Thus, the nozzle 42 and the shielding plate 48 can be brought close to or separated from the spin base 53. Specifically, when the control unit 13 controls the operation of the elevating mechanism 49 and the substrate W is loaded and unloaded into and from the treating unit 1, the nozzle 42 and the shielding plate 48 are raised to a separation position above a spin chuck 55 (position shown in FIG. 2), and when a sublimation process described below is performed, the nozzle 42 and the shielding plate 48 are lowered to a height position at which a separation distance set with respect to the front surface Wf of the substrate W is obtained. Note that the elevating mechanism 49 is fixedly provided in the chamber 11.

The support shaft 44 has a hollow substantially cylindrical shape, and a gas supply pipe (not shown) is inserted to the inside of the support shaft 44. Then, the gas supply pipe communicates with the pipe 45. This allows the nitrogen gas stored in the gas storage portion 47 to flow through the gas supply pipe. In addition, the end of the gas supply pipe is connected to the nozzle 42 described above.

The shielding plate 48 has a disk-like shape having an any thickness having an opening at a central portion, and is attached substantially horizontally to a lower end portion of the support shaft 44. The lower surface of the shielding plate 48 is a substrate-facing surface facing the front surface Wf of the substrate W, and is substantially parallel to the front surface Wf of the substrate W. In addition, the shielding plate 48 is formed to have a size having a diameter equal to or larger than the diameter of the substrate W. Further, the shielding plate 48 is provided such that the nozzle 42 is positioned at the opening of the shielding plate 48. Note that the shielding plate rotation mechanism that includes an electric motor or the like is connected to the shielding plate 48. The shielding plate rotation mechanism rotates the shielding plate 48 about a rotation axis C1 with respect to the support shaft 44 in accordance with an operation rotation command from the control unit 13. In addition, the shielding plate rotation mechanism can be rotated in synchronization with the rotation of the substrate W in the sublimation process described below.

In the gas tank 471, at least a gas that is inert with respect to the substrate treating liquid (sublimable substance), more specifically, a nitrogen gas is stored. In addition, the nitrogen gas is adjusted to a temperature equal to or lower than the freezing point of the sublimable substance in the gas temperature adjustment portion 472. The temperature of the nitrogen gas is not particularly limited as long as it is a temperature equal to or lower than the freezing point of the sublimable substance, but can be usually set within a range of 0° C. or more and 15° C. or less. By setting the temperature of the nitrogen gas to 0° C. or more, it is possible to prevent water vapor present inside the chamber 11 from freezing and adhering to the front surface Wf of the substrate W, and to prevent adverse effects on the substrate W from occurring.

In addition, the nitrogen gas used in the present embodiment is preferably a dry gas having a dew point of 0° C. or less. When the nitrogen gas is blown against the solidified film of the substrate treating liquid under an atmospheric pressure environment, the sublimable substance contained in the solidified film is sublimated in the nitrogen gas. Since the nitrogen gas is continuously supplied to the solidified film, the partial pressure of the sublimable substance in a gaseous state generated by the sublimation in the nitrogen gas is maintained in a state lower than a saturated vapor pressure of the sublimable substance in a gaseous state at the temperature of the nitrogen gas, and at least the surface of the solidified film is present in an atmosphere in which the sublimable substance in a gaseous state is present at a pressure equal to or lower than the saturated vapor pressure.

In addition, in the present embodiment, the nitrogen gas is used as a gas stored in the gas storage portion 47, but the embodiment of the present disclosure is not limited thereto as long as the gas is inert with respect to the sublimable substance. Examples of the gas as an alternative to the nitrogen gas include argon gas, helium gas, and air (gas with nitrogen gas concentration of 80% and oxygen gas concentration of 20%). Alternatively, a mixed gas obtained by mixing this plurality of types of gases may be used. In addition, a dry inert gas in which the amount of moisture contained in these gases is reduced to a certain value or less may be used. The amount of moisture contained in the dry inert gas is preferably 1000 ppm or less, more preferably 100 ppm or less, and particularly preferably 10 ppm or less. When the amount of moisture in the dry inert gas is 1000 ppm or less, condensation during the sublimation process can be prevented.

Note that the gas supply portion 41 may have a configuration in which a substrate treating liquid supply portion is incorporated. In this case, the nozzle 22 of the substrate treating liquid supply portion is provided at the front end of the support shaft 44 so as to coexist with the nozzle 42 for discharging the inert gas or the like. In addition, a supply pipe (not shown) for supplying the substrate treating liquid is also inserted into the support shaft 44, and the supply pipe is configured to communicate with the pipe 25. This allows the substrate treating liquid stored in the substrate treating liquid storage portion 27 to flow through the supply pipe.

The dispersion prevention cup 12 is provided so as to surround the spin base 53. The dispersion prevention cup 12 is connected to an elevating drive mechanism, which is not shown, and can be elevated in the Z direction. When the substrate treating liquid or the IPA is supplied to the pattern-formed surface of the substrate W, the dispersion prevention cup 12 is positioned at a predetermined position as shown in FIG. 2 by the elevating drive mechanism, and surrounds the substrate W held by the chuck pins 54 from a side position. Thus, a liquid such as the substrate treating liquid or the IPA dispersed from the substrate W or the spin base 53 can be collected.

Note that the substrate treating apparatus 100 of the present embodiment may further include, in the treating unit 1, a chemical liquid supply unit that supplies a chemical liquid to the pattern-formed surface of the substrate W and a rinse liquid supply unit that supplies a rinse liquid to the pattern-formed surface.

As the chemical liquid supply unit and the rinse liquid supply unit, for example, as with the IPA supply portion 31, a unit including a nozzle, an arm, a turning shaft, a pipe, a valve, and a chemical liquid storage tank can be adopted. Therefore, detailed description of the units will be omitted. Note that examples of the chemical liquid supplied by the chemical liquid supply unit include a chemical liquid containing at least one of sulfuric acid, nitric acid, hydrochloric acid, fluoric acid, phosphoric acid, acetic acid, aqueous ammonia, aqueous hydrogen peroxide, an organic acid (for example, citric acid, oxalic acid, or the like), an organic alkali (for example, TMAH: tetramethylammonium hydroxide or the like), a surfactant, and a corrosion inhibitor. In addition, the rinse liquid supplied by the rinse liquid supply unit may be, for example, any of deionized water (DIW), carbonated water, electrolyzed ionized water, hydrogen water, ozonated water, and hydrochloric acid water having a dilution concentration (for example, about 10 to 100 ppm).

### <Configuration of Control Unit>

The control unit 13 is electrically connected to each portion of the treating unit 1 (see FIGS. 2 to 4) and controls the operation of each portion. The control unit 13 includes a computer including an arithmetic processing portion and a memory. As the arithmetic processing portion, a CPU that performs various arithmetic processing is used. In addition, the memory includes ROM that is read-only memory for storing a substrate treating program, RAM that is readable/writable memory for storing various types of information, and a magnetic disk for storing control software, data, and the like. In the magnetic disk, substrate treating condition information (treatment recipe) according to the substrate W, control condition information for controlling the treating unit 1, and the like are stored in advance. The CPU reads the substrate treating condition information, the control condition information, and the like into the RAM, and controls each portion of the treating unit 1 according to the contents of the information.

### (Substrate Treating Method)

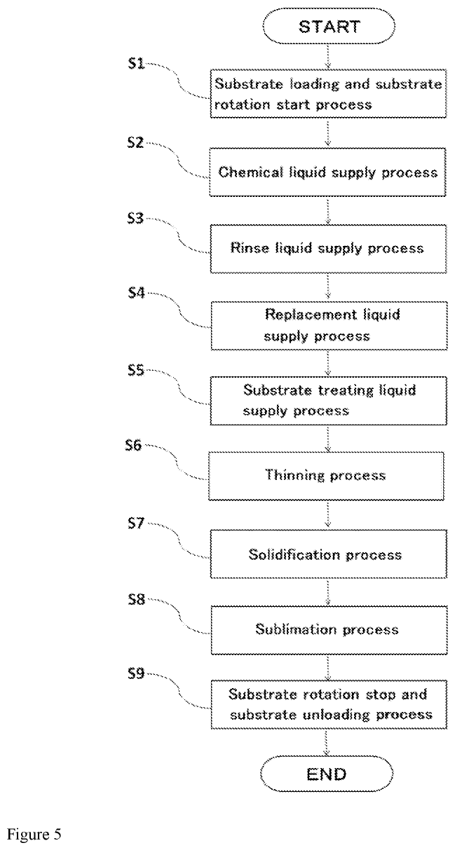

Next, the substrate treating method using the substrate treating apparatus 100 of the present embodiment will be described below with reference to FIGS. 5 to 8.

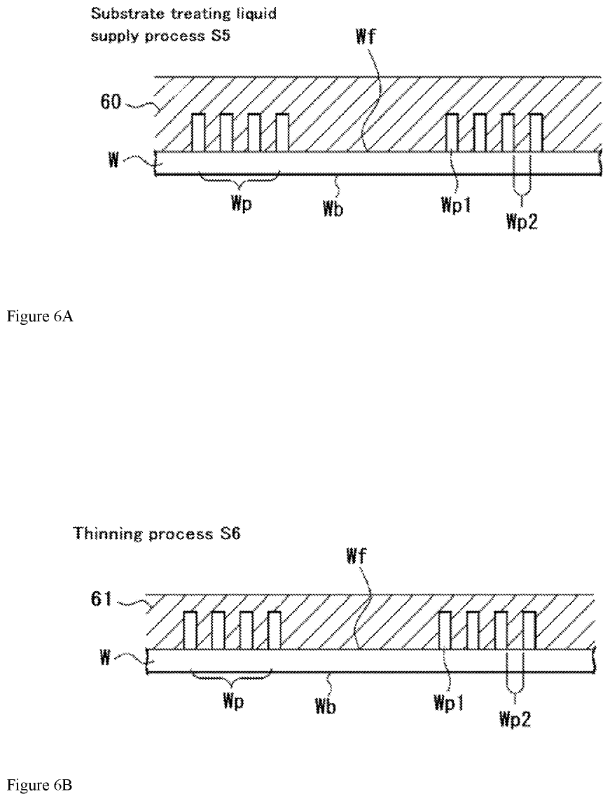

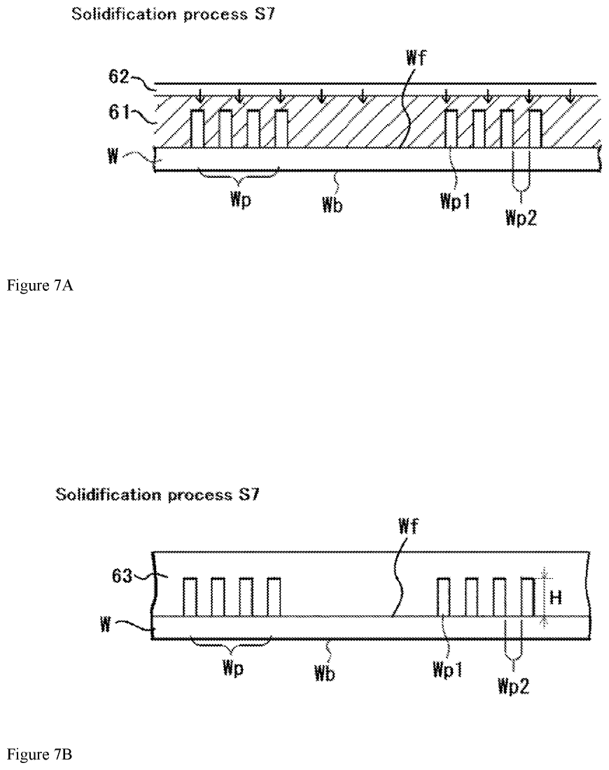

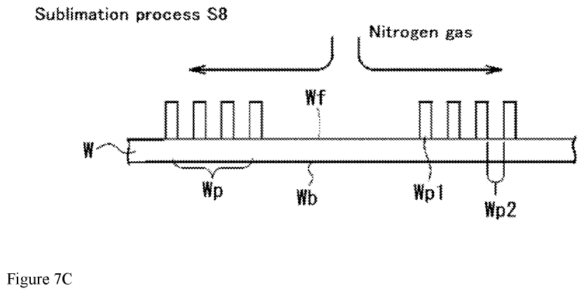

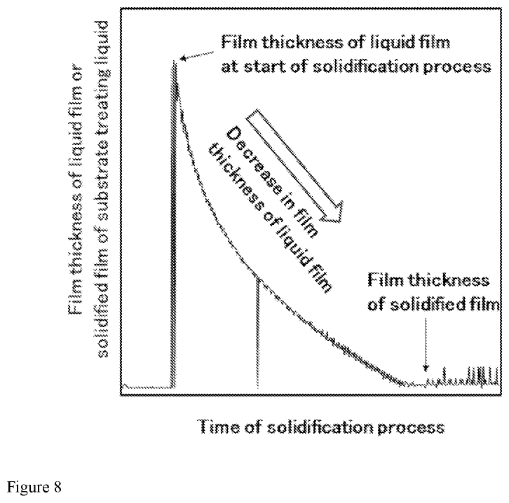

FIG. 5 is a flowchart for describing the substrate treating method using the substrate treating apparatus 100 according to the present embodiment. FIG. 6A is a schematic view showing a state of the substrate W after the end of a substrate treating liquid supply process, and FIG. 6B is a schematic view showing a state of the substrate W after the end of a thinning process. FIG. 7A is a schematic view showing a state of the substrate W at the start of a solidification process, FIG. 7B is a schematic view showing a state in which a solidified film 63 is formed on the front surface Wf of the substrate W, and FIG. 7C is a schematic view showing a state in which the solidified film 63 is removed by sublimation. FIG. 8 is a graph showing an example of an image in which a thickness of a liquid film (thin film) of the substrate treating liquid on the substrate W decreases due to evaporation of a solvent.

Note that, on the substrate W, a protrusion and recess pattern Wp is formed in a front-end process (see FIG. 6A or the like). The pattern Wp includes a protrusion Wp1 and a recess Wp2. In the present embodiment, the protrusion Wp1 has, for example, a height in a range of 100 nm to 600 nm and a width in a range of 5 nm to 50 nm. In addition, the shortest distance between two adjacent protrusions Wp1 (the shortest width of the recess Wp2) is, for example, in a range of 5 to 150 nm. The aspect ratio of the protrusion Wp1, that is, the value (height/width) obtained by dividing the height by the width is, for example, in a range of 5 to 35.

The substrate treating method according to the present embodiment includes a substrate loading and substrate rotation start process S1, a chemical liquid supply process S2, a rinse liquid supply process S3, a replacement liquid supply process S4, a substrate treating liquid supply process S5, a thinning process S6, a solidification process S7, a sublimation process S8, and a substrate rotation stop and substrate unloading process S9. Each of these processes is processed under an atmospheric pressure environment unless otherwise specified. Here, the atmospheric pressure environment refers to an environment of 0.7 atm to 1.3 atm around standard atmospheric pressure (1 atm, 1013 hPa). In particular, when the substrate treating apparatus 100 is disposed in a clean room having a positive pressure, the environment of the front surface Wf of the substrate W is higher than 1 atm.

### Step S1: Substrate Loading and Substrate Rotation Start Process

First, a substrate treating program corresponding to a predetermined substrate W is instructed to be executed by an operator. Thereafter, as preparation for loading the substrate W into the treating unit 1, the control unit 13 issues an operation command and performs the operation described below. That is, the rotation of the rotation drive portion 52 is stopped, and the chuck pins 54 are positioned at a position suitable for delivery of the substrate W. In addition, the valves 26, 36, and 46 are closed, and the nozzles 22, 32, and 42 are positioned at respective retracted positions. Then, the chuck pins 54 are brought into an open state by an opening and closing mechanism, which is not shown.

When the untreated substrate W housed in the container C of the indexer portion 120 in a sealed state is loaded into the treating unit 1 by the first conveyance portion 122 and the second conveyance portion 111 and placed on the chuck pins 54, the chuck pins 54 are brought into a closed state by the opening and closing mechanism, which is not shown. Thus, the untreated substrate W is held by the substrate holding portion 51. The untreated substrate W is held by the substrate holding portion 51 so as to be in a substantially horizontal pose.

Subsequently, the rotation drive portion 52 of the substrate holding portion 51 rotates the spin base 53 in accordance with an operation command of the control unit 13. Thus, the substrate W held by the chuck pins 54 above the spin base 53 is rotated about the rotation axis. The rotation speed (rotational frequency) of the spin chuck 55 (rotation speed (rotational frequency) of the substrate W) can be set within a range of, for example, about 10 rpm to 3000 rpm, preferably 800 to 1200 rpm.

### Step S2: Chemical Liquid Supply Process

Next, in a state where the substrate W is rotated by the substrate holding portion 51, the chemical liquid is supplied from the chemical liquid supply unit onto the front surface Wf of the substrate W in accordance with an operation command of the control unit 13. Thus, a native oxide film formed on the front surface Wf of the substrate W is etched. After the end of the etching, the supply of the chemical liquid is stopped.

### Step S3: Rinse Liquid Supply Process

Next, in a state where the substrate W is rotated by the substrate holding portion 51, the rinse liquid is supplied from the rinse liquid supply unit onto the front surface Wf of the substrate W in accordance with an operation command of the control unit 13. The rinse liquid supplied to the front surface Wf flows from the vicinity of the center of the front surface Wf of the substrate W toward the peripheral edge portion of the substrate W by a centrifugal force generated by the rotation of the substrate W, and diffuses to the entire front surface Wf of the substrate W. Thus, the chemical liquid adhering to the front surface Wf of the substrate W is removed by the supply of the rinse liquid, and the entire front surface Wf of the substrate W is covered with the rinse liquid. After the entire front surface Wf of the substrate W is covered with the rinse liquid, the supply of the rinse liquid is stopped.

### Step S4: Replacement Liquid Supply Process

Next, in a state where the substrate W is rotated by the substrate holding portion 51, the IPA as a replacement liquid is supplied onto the front surface Wf of the substrate W. That is, the control unit 13 gives an operation command to the turning drive portion 14 and positions the nozzle 32 at a central portion of the front surface Wf of the substrate W. Then, the control unit 13 gives an operation command to the valve 36 and opens the valve 36. Thus, the IPA is supplied from the IPA tank 37 to the front surface Wf of the substrate W via the pipe 35 and the nozzle 32.

The IPA supplied to the front surface Wf of the substrate W flows from the vicinity of the center of the front surface Wf of the substrate W toward the peripheral edge portion of the substrate W by a centrifugal force generated by the rotation of the substrate W, and diffuses to the entire front surface Wf of the substrate W. Thus, the rinse liquid adhering to the front surface Wf of the substrate W is removed by the supply of the IPA, and the entire front surface Wf of the substrate W is covered with the IPA. The rotation speed of the substrate W is preferably set to such an extent that the film thickness of a film made of the IPA is higher than the height of the protrusion Wp1 on the entire front surface Wf. In addition, the supply amount of the IPA is not particularly limited, and can be appropriately set. At the end of the replacement liquid supply process, the control unit 13 gives an operation command to the valve 36 and closes the valve 36. In addition, the control unit 13 gives an operation command to the turning drive portion 14 and positions the nozzle 32 at the retracted position.

### Step S5: Substrate Treating Liquid Supply Process

Next, the substrate treating liquid is supplied to the front surface Wf of the substrate W to which the IPA adheres.

That is, the control unit 13 gives an operation command to the rotation drive portion 52 and rotates the substrate W about the axis A1 at a constant speed. Subsequently, the control unit 13 gives an operation command to the turning drive portion 14 and positions the nozzle 22 at a central portion of the front surface Wf of the substrate W. Then, the control unit 13 gives an operation command to the valve 26 and opens the valve 26. Thus, the substrate treating liquid is supplied from the substrate treating liquid storage tank 271 to the front surface Wf of the substrate W via the pipe 25 and the nozzle 22. The substrate treating liquid supplied to the front surface Wf of the substrate W flows from the vicinity of the center of the front surface Wf of the substrate W toward the peripheral edge portion of the substrate W by a centrifugal force generated by the rotation of the substrate W, and diffuses to the entire front surface Wf of the substrate W. Thus, as shown in FIG. 6A, the IPA adhering to the front surface Wf of the substrate W is removed by the supply of the treating liquid, the entire front surface Wf of the substrate W is covered with the substrate treating liquid, and a liquid film 60 of the substrate treating liquid is formed.

At the end of the substrate treating liquid supply process, the control unit 13 gives an operation command to the valve 26, and closes the valve 26. In addition, the control unit 13 gives an operation command to the turning drive portion 14 and positions the nozzle 22 at the retracted position.

### Step S6: Thinning Process

Subsequently, the liquid film 60 of the substrate treating liquid formed on the front surface Wf of the substrate W is thinned.

That is, the control unit 13 gives an operation command to the rotation drive portion 52 and rotates the substrate W about the axis A1 at a constant speed (first rotation speed). Thus, the excessive substrate treating liquid is shaken off from the front surface Wf of the substrate W by utilizing the action of the centrifugal force generated by the rotation of the substrate W. By shaking off from the front surface Wf of the substrate W, the liquid film 60 can be made into a thin film 61 having an optimum film thickness as shown in FIG. 6B. Note that, in the substrate treating liquid supply process, when the liquid film 60 can be thinned by controlling the supply amount of the substrate treating liquid, the rotation speed of the substrate W, and the like, the present process may be omitted.

In the present process, the first rotation speed of the substrate W is set according to the film thickness of the liquid film 60. The first rotation speed is usually set within a range of 100 rpm or more and 1500 rpm or less, preferably 100 rpm or more and 1000 rpm or less, and more preferably 100 rpm or more and 500 rpm or less in terms of rotational frequency.

### Step S7: Solidification Process

Next, the solvent is evaporated from the thin film 61 of the substrate treating liquid, the sublimable substance is deposited, and a solidified film is formed.

That is, the control unit 13 gives an operation command to the rotation drive portion 52 and rotates the substrate W about the axis A1 at a second rotation speed higher than the first rotation speed. Since the vapor pressure of the solvent is higher than the vapor pressure of the sublimable substance corresponding to the solute, the solvent evaporates at an evaporation rate higher than an evaporation rate of the sublimable substance. Therefore, as shown in FIG. 7A, the solvent in the thin film 61 starts evaporating. Then, as shown in FIG. 8, the film thickness of the thin film 61 gradually decreases while the concentration of the sublimable substance gradually increases.

Further, when the sublimable substance in the thin film 61 is brought into a supersaturated state, the sublimable substance starts depositing, a solidified film 62 is formed from a surface layer portion of the thin film 61, and then the solidified film 63 covering the entire front surface Wf of the substrate W is formed as shown in FIG. 7B.

Here, the film thickness of the solidified film 63 is preferably within a range of a predetermined ratio with respect to a height H of the protrusion Wp1 (pattern) on the pattern-formed surface. More specifically, for example, when 2,5-dimethyl-2,5-hexanediol is used as the sublimable substance, the film thickness is preferably within a range of 85% or more and 365% or less, and more preferably within a range of 89% or more and 360% or less with respect to the height H. In addition, when 3-trifluoromethylbenzoic acid is used as the sublimable substance, the film thickness is preferably within a range of 80% or more and 200% or less, more preferably within a range of 85% or more and 190% or less with respect to the height H. When the ratio of the film thickness of the solidified film 63 with respect to the height H of the protrusion Wp1 is within these numerical ranges, the collapse of the pattern can be more favorably suppressed.

Note that the film thickness of the solidified film 63 can be controlled by adjusting the concentration of the sublimable substance in the substrate treating liquid. Then, in the present disclosure, by using 2,5-dimethyl-2,5-hexanediol and 3-trifluoromethylbenzoic acid as the sublimable substance, the range of the film thickness of the solidified film that can favorably suppress the collapse of the pattern can be made relatively wider as compared with a conventional sublimable substance. That is, by the substrate treating method of the present disclosure, with respect to the film thickness of the solidified film 63, the range of conditions under which the collapse of the pattern can be favorably suppressed can be set wide, and the process window is excellent.

### Step S8: Sublimation Process

Subsequently, the solidified film 63 formed on the front surface Wf of the substrate W is sublimated and removed.

That is, when the control unit 13 gives an operation command to the elevation drive portion 16, the elevating mechanism 49 lowers the nozzle 42 and the shielding plate 48 until the separation distance from the front surface Wf of the substrate W reaches a preset value, and brings the nozzle 42 and the shielding plate 48 close to the substrate W. After the nozzle 42 and the shielding plate 48 are brought close to the front surface Wf of the substrate W at the setting separation distance, the control unit 13 rotates the shielding plate 48 about the axis A1 at a constant speed so as to be synchronized with the substrate W.

Subsequently, the control unit 13 gives an operation command to the valve 46 and opens the valve 46. Thus, the inert gas is supplied from the gas tank 471 toward the front surface Wf of the substrate W via the pipe 45 and the nozzle 42. At this time, since the substrate W and the shielding plate 48 rotate synchronously, the inert gas flows from the vicinity of the center of the front surface Wf of the substrate W toward the peripheral edge portion of the substrate W by a centrifugal force generated by the rotation, and diffuses to the entire front surface Wf of the substrate W. Thus, the contact speed between the solidified film 63 and the inert gas can be increased, and the sublimation of the solidified film 63 can be promoted.

In addition, the air present on the front surface Wf of the substrate W can be replaced with the inert gas. Then, by replacing with the inert gas, the solidified film 63 formed on the front surface Wf can be placed under the flow of the inert gas and prevent exposure to the air or the like, and the solidified film 63 can be sublimated while maintaining the space between the substrate W and the shielding plate 48 in a low temperature state. Then, the heat of sublimation is removed along with the sublimation of the solidified film 63, and the solidified film 63 is maintained at a temperature equal to or lower than the freezing point (melting point) of the sublimable substance. Therefore, the sublimable substance contained in the solidified film 63 can be effectively prevented from melting. Thus, as shown in FIG. 7C, since there is no liquid phase between the patterns on the front surface Wf of the substrate W, the substrate W can be dried while suppressing the occurrence of the collapse of the pattern.

The flow rate of the inert gas is preferably 200 l/min or less, more preferably 50 l/min or more and 200 l/min or less, and still more preferably 40 l/min or more and 50 l/min or less. By setting the flow rate of the inert gas to 200 l/min or less, the collapse of the pattern caused by blowing of the inert gas can be prevented. In addition, the discharge time of the inert gas can be appropriately set according to the sublimation time of the sublimable substance.

When a predetermined sublimation time elapses from the start of the sublimation process S8, the control unit 13 gives an operation command to the valve 46 and closes the valve 46.

Step S9: Substrate Rotation Stop and Substrate Unloading Process After the end of the sublimation process S8, the control unit 13 gives an operation command to the rotation drive portion 52 and stops the rotation of the spin base 53. In addition, the control unit 13 controls the shielding plate rotation mechanism and stops the rotation of the shielding plate 48. The control unit 13 also controls the elevation drive portion 16, and the shielding plate 48 is raised from a shielding position and is positioned at the retracted position.

Thereafter, the second conveyance portion 111 enters the internal space of the chamber 11, and unloads the treated substrate W released from being held by the chuck pins 54 to the outside of the chamber 11, and ends the series of substrate drying treatment.

As described above, in the present embodiment, by using a substrate treating liquid containing a sublimable substance of at least one of 2,5-dimethyl-2,5-hexanediol and 3-trifluoromethylbenzoic acid, it is possible to favorably suppress the collapse of the pattern on the substrate W as compared with a sublimation drying technique using a conventional sublimable substance. In particular, in the present embodiment, even in the case of a pattern having a noticeably low mechanical strength, the occurrence of the collapse of the pattern can be noticeably effectively suppressed.

### MODIFICATION

In the above description, a preferred embodiment of the present disclosure has been described. However, the present disclosure is not limited to the embodiment, and can be implemented in various other forms. Other main forms will be exemplified below.

In the embodiment described above, the case where the sublimation process S8 is performed after the solidification process S7 is ended has been described. However, the present disclosure is not limited to this aspect. For example, the sublimation process S8 may be started after the start of the solidification process S7 and performed in parallel with the solidification process S7. As described above, the sublimable substance is deposited by evaporation of the solvent, and the solidified film is formed from the surface layer portion of the liquid film. Therefore, the sublimation process S8 may be started before the end of the solidification process S7. Thus, the sublimation drying of the substrate W can be performed in a short period of time.

In addition, in the above-described embodiment, the case where the gas supply portion includes the shielding plate has been described as an example. However, the present disclosure is not limited to this aspect, and for example, the sublimation process S8 may be performed using a gas supply portion not including a shielding plate.

Hereinafter, preferred examples of this invention will be exemplarily described in detail. However, the materials, blending amounts, and the like described in the examples are not intended to limit the scope of this invention only to the materials, blending amounts, and the like unless otherwise limited.

### (Patterned Substrate)

A silicon substrate having a model pattern formed on a surface was prepared as a patterned substrate, and a coupon (specimen) having a square of 1 cm sides was cut out from the silicon substrate. As a model pattern, a pattern in which columns having a height of about 300 nm were arranged was adopted.

### EXAMPLE 1

In the present Example, the sublimation drying treatment was performed by a procedure described below using the coupon cut out from the silicon substrate described above, and the effect of suppressing the pattern collapse was evaluated.

First, the coupon was immersed in hydrofluoric acid having a concentration of 10 mass % for 20 seconds (chemical liquid supply process), and then immersed in DIW for one minute to be rinsed (rinse liquid supply process). Further, the coupon after rinsing with the DIW was immersed in IPA for one minute, and the DIW present on the pattern-formed surface on the coupon was replaced with the IPA (replacement liquid supply process).

Subsequently, the coupon in which the IPA remained on the surface was immersed in a substrate treating liquid (liquid temperature: 25° C.) at room temperature (25° C.) and atmospheric pressure (1 atm) for 30 seconds, and the IPA present on the pattern-formed surface on the coupon was replaced with the substrate treating liquid (substrate treating liquid supply process). In addition, as the substrate treating liquid, a substrate treating liquid containing 2,5-dimethyl-2,5-hexanediol having a concentration of 2.3 vol % (sublimable substance) and the IPA was used.

Further, the coupon after the supply of the substrate treating liquid was rotated about the rotation axis at a rotation speed of 10 rpm for 5 seconds, and the liquid film of the substrate treating liquid on the pattern-formed surface was made thin (thinning process).

Subsequently, the coupon after the thinning process was rotated about the rotation axis at a rotation speed of 1500 rpm, the IPA was evaporated, 2,5-dimethyl-2,5-hexanediol was deposited, and a solidified film made of 2,5-dimethyl-2,5-hexanediol was formed (solidification process).

After the solidified film was formed on the pattern-formed surface of the coupon, a nitrogen gas was blown to the solidified film, and the solidified film was sublimated (sublimation process). In addition, the sublimation process was performed while the coupon was rotated about the rotation axis at a rotation speed of 1500 rpm. Further, the flow rate of the nitrogen gas was set to 40/min. Note that the entire treatment time of the solidification process and the sublimation process was set to 120 seconds.

For the coupon after the sublimation drying obtained as described above, the collapse rate of the pattern was calculated from a SEM image, and the effect of suppressing the pattern collapse on the pattern-formed surface was evaluated based on the collapse rate. Note that the collapse rate is obtained by calculating the collapse rates of any seven regions using the formula described below and setting an average value as the collapse rate.

Collapse rate (%)=(the number of collapsed protrusions in any regions)/(total number of protrusions in the regions)×100

As a result, the collapse rate after the drying treatment was 7.83% as compared with the pattern-formed surface of the coupon before the drying treatment. Thus, it was confirmed that when 2,5-dimethyl-2,5-hexanediol was used as the sublimable substance, the collapse of the pattern was noticeably favorably suppressed and the sublimation drying was effective.

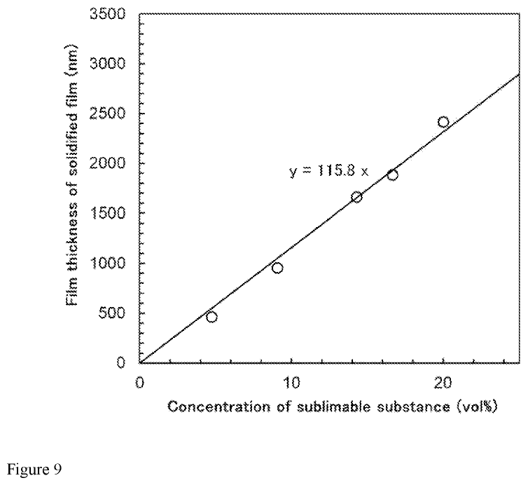

In addition, the film thickness of the solidified film made of 2,5-dimethyl-2,5-hexanediol formed in the present Example was calculated using a concentration calibration curve. The concentration calibration curve shown in FIG. 9 was used, and the film thickness of the solidified film was calculated from the concentration calibration curve on the basis of the equation described below. As a result, in the present Example, the film thickness of the solidified film was 270 nm. This corresponded to 89% of the height (300 nm) of the pattern of the coupon.

Film thickness (nm) of solidified film=inclination of calibration curve (115.8 nm/vol %)×concentration of sublimable substance in substrate treating liquid (vol %)

Note that FIG. 9 is a graph showing a concentration calibration curve between a concentration of cyclohexanone oxime in the substrate treating liquid and a film thickness of a solidified film formed of cyclohexanone oxime. Since the inclination of the concentration calibration curve does not greatly change depending on the type of sublimable substance, which is a solute, the concentration calibration curve of cyclohexanone oxime was used in the present experimental example.

### EXAMPLE 2

In the present Example, the concentration of 2,5-dimethyl-2,5-hexanediol in the substrate treating liquid was changed to 3.2 vol %. Those other than the above were as in the Example 1, and the effect of suppressing the pattern collapse on the pattern-formed surface was evaluated. As a result, the collapse rate was 0.86%.

In addition, in the same manner as in Example 1, the film thickness of the solidified film was also calculated using the concentration calibration curve shown in FIG. 9. As a result, the film thickness of the solidified film was 370 nm. This corresponded to 124% of the height (300 nm) of the pattern of the coupon.

### EXAMPLE 3

In the present Example, the concentration of 2,5-dimethyl-2,5-hexanediol in the substrate treating liquid was changed to 4.8 vol %. Those other than the above were as in the Example 1, and the effect of suppressing the pattern collapse on the pattern-formed surface was evaluated. As a result, the collapse rate was 1.69%.

In addition, in the same manner as in Example 1, the film thickness of the solidified film was also calculated using the concentration calibration curve shown in FIG. 9. As a result, the film thickness of the solidified film was 560 nm. This corresponded to 185% of the height (300 nm) of the pattern of the coupon.

### EXAMPLE 4

In the present Example, the concentration of 2,5-dimethyl-2,5-hexanediol in the substrate treating liquid was changed to 6.3 vol %. Those other than the above were as in the Example 1, and the effect of suppressing the pattern collapse on the pattern-formed surface was evaluated. As a result, the collapse rate was 10.1%.

In addition, in the same manner as in Example 1, the film thickness of the solidified film was also calculated using the concentration calibration curve shown in FIG. 9. As a result, the film thickness of the solidified film was 730 nm. This corresponded to 243% of the height (300 nm) of the pattern of the coupon.

### EXAMPLE 5

In the present Example, the concentration of 2,5-dimethyl-2,5-hexanediol in the substrate treating liquid was changed to 9.2 vol %. Those other than the above were as in the Example 1, and the effect of suppressing the pattern collapse on the pattern-formed surface was evaluated. As a result, the collapse rate was 3.70%.

In addition, in the same manner as in Example 1, the film thickness of the solidified film was also calculated using the concentration calibration curve shown in FIG. 9. As a result, the film thickness of the solidified film was 1100 nm. This corresponded to 360% of the height (300 nm) of the pattern of the coupon.

### EXAMPLE 6

In the present Example, 3-trifluoromethylbenzoic acid was used as a sublimable substance, and the concentration of 3-trifluoromethylbenzoic acid was changed to 2.2 vol % with respect to the substrate treating liquid. Those other than the above were as in Example 1, and the effect of suppressing the pattern collapse on the pattern-formed surface was evaluated. As a result, the collapse rate was 3.27%.

In addition, since the inclination of the concentration calibration curve does not greatly change depending on the type of sublimable substance, which is a solute, the film thickness of the solidified film was also calculated using the concentration calibration curve in FIG. 9 as in Example 1. As a result, the film thickness of the solidified film was 250 nm. This corresponded to 85% of the height (300 nm) of the pattern of the coupon.

### EXAMPLE 7

In the present Example, the concentration of 3-trifluoromethylbenzoic acid with respect to the substrate treating liquid was changed to 3.2 vol %. Those other than the above were as in the Example 6, and the effect of suppressing the pattern collapse on the pattern-formed surface was evaluated. As a result, the collapse rate was 13.2%.

In addition, in the same manner as in Example 6, the film thickness of the solidified film was also calculated using the concentration calibration curve shown in FIG. 9. As a result, the film thickness of the solidified film was 370 nm. This corresponded to 124% of the height (300 nm) of the pattern of the coupon.

### EXAMPLE 8

In the present Example, the concentration of 3-trifluoromethylbenzoic acid with respect to the substrate treating liquid was changed to 5.0 vol %. Those other than the above were as in the Example 6, and the effect of suppressing the pattern collapse on the pattern-formed surface was evaluated. As a result, the collapse rate was 11.1%.

In addition, in the same manner as in Example 6, the film thickness of the solidified film was also calculated using the concentration calibration curve shown in FIG. 9. As a result, the film thickness of the solidified film was 580 nm. This corresponded to 190% of the height (300 nm) of the pattern of the coupon.

| | | Concentration | | Film | Ratio of film |
|---|---|---|---|---|---|
| | | of sublimable | | thickness of | thickness of |
| | Type of sublimable | substance | Collapse | solidified | solidified film to |
| | substance | (vol %) | rate (%) | film (nm) | pattern height (%) |
| Example 1 | 2,5-dimethyl-2,5- | 2.3 | 7.83 | 270 | 89 |
| Example 2 | hexanediol | 3.2 | 0.86 | 370 | 124 |
| Example 3 | | 4.8 | 1.69 | 560 | 185 |
| Example 4 | | 6.3 | 10.1 | 730 | 243 |
| Example 5 | | 9.2 | 3.70 | 1100 | 360 |
| Example 6 | 3-trifluoromethylbenzoic | 2.2 | 3.27 | 250 | 85 |
| Example 7 | acid | 3.2 | 13.2 | 370 | 124 |
| Example 8 | | 5.0 | 11.1 | 580 | 190 |

The present disclosure can be applied to a drying technique for removing liquid adhering to the pattern-formed surface of a substrate and a substrate treating technique for treating a surface of the substrate using the drying technique in general.

1. A substrate treating method for treating a pattern-formed surface of a substrate, the substrate treating method comprising:
a supply process of supplying a substrate treating liquid containing a sublimable substance and a solvent to the pattern-formed surface;
a solidification process of evaporating the solvent in a liquid film of the substrate treating liquid supplied to the pattern-formed surface in the supply process, depositing the sublimable substance, and forming a solidified film containing the sublimable substance; and
a sublimation process of sublimating the solidified film and removing the solidified film,
wherein the sublimable substance contains at least one of 2,5-dimethyl-2,5-hexanediol and 3-trifluoromethylbenzoic acid.

2. The substrate treating method according to claim 1, further comprising:
a thinning process of thinning the liquid film of the substrate treating liquid supplied in the supply process onto the pattern-formed surface by rotating the substrate at a first rotation speed about a rotation axis parallel to a direction perpendicular to the pattern-formed surface,
wherein the solidification process is a process of rotating the substrate about the rotation axis at a second rotation speed higher than the first rotation speed and evaporating the solvent in the liquid film.

3. The substrate treating method according to claim 2, wherein
a solvent having a higher vapor pressure at room temperature than the sublimable substance is used as the solvent.

4. The substrate treating method according to claim 3, wherein
the solvent is at least one of methanol, butanol, isopropyl alcohol, and acetone.

5. A substrate treating apparatus for treating a pattern-formed surface of a substrate, the substrate treating apparatus comprising:
a substrate holding portion that rotatably holds the substrate about a rotation axis parallel to a direction perpendicular to the pattern-formed surface;
a supply portion that supplies a substrate treating liquid containing a sublimable substance and a solvent to the pattern-formed surface of the substrate held by the substrate holding portion; and
a sublimation portion that sublimates a solidified film containing the sublimable substance and remove the solidified film,
wherein the substrate holding portion evaporates the solvent in a liquid film of the substrate treating liquid supplied to the pattern-formed surface by the supply portion, deposits the sublimable substance, and forms the solidified film containing the sublimable substance, and
the sublimable substance in the substrate treating liquid supplied by the supply portion contains at least one of 2,5-dimethyl-2,5-hexanediol and 3-trifluoromethylbenzoic acid.

6. The substrate treating apparatus according to claim 5, wherein
the substrate holding portion
thins the liquid film of the substrate treating liquid supplied to the pattern-formed surface by the supply portion by rotating the substrate about the rotation axis, and
rotates the substrate about the rotation axis at a second rotation speed higher than a first rotation speed when the liquid film of the substrate treating liquid is thinned and evaporates the solvent in the liquid film.

7. The substrate treating apparatus according to claim 6, wherein
a solvent having a higher vapor pressure at room temperature than the sublimable substance is used as the solvent.

8. The substrate treating apparatus according to claim 7, wherein
the solvent is at least one of methanol, butanol, isopropyl alcohol, and acetone.

9. A substrate treating liquid used for removing a liquid on a substrate having a pattern-formed surface, the substrate treating liquid comprising:
a sublimable substance; and
a solvent,
wherein the sublimable substance contains at least one of 2,5-dimethyl-2,5-hexanediol and 3-trifluoromethylbenzoic acid.

10. The substrate treating liquid according to claim 9, wherein
the solvent has a higher vapor pressure at room temperature than the sublimable substance.

11. The substrate treating liquid according to claim 10, wherein
the solvent is at least one of methanol, butanol, isopropyl alcohol, and acetone.
